(19) United States
(12) Patent Application Publication
(10) Pub. No.: US 2026/0231823 A1
(43) Pub. Date: Aug. 6, 2026

(54) DEVICE PACKAGE WIRE BONDING ENHANCEMENTS

(71) Applicant: MACOM Technology Solutions Holdings, Inc., Lowell, MA (US)

(72) Inventors: Eng Wah Woo, IPOH (MY); Hui Min Cheang, IPOH (MY); Ling Foong Ooi, IPOH (MY); Soon Lee Liew, IPOH (MY); Carlos Macias, Aliso Viejo, CA (US)

(21) Appl. No.: 19/047,253

(22) Filed: Feb. 6, 2025

(51) Int. Cl. H01L 23/00; H01L 23/043; H01L 23/498; H01L 25/07; H10D 80/20

(52) U.S. Cl. CPC H10W 90/00; H10D 80/251; H10W 70/658; H10W 70/66; H10W 72/07511; H10W 72/07532; H10W 72/07533; H10W 72/5363; H10W 72/5445; H10W 72/552; H10W 72/5522; H10W 72/5525; H10W 72/59; H10W 72/952; H10W 76/13; H10W 90/753; H10W 90/756

(57) ABSTRACT

Semiconductor device packages including wire bond and wire bonding enhancements are described. An example semiconductor device package includes a semiconductor device having a bond pad, a package cover over the semiconductor device, and a bond wire including Copper that is electrically coupled to the bond pad of the semiconductor device. The bond wire includes a wedge bond at the bond pad. The package can also include a package lead, and the bond wire can extend between and be electrically coupled to the bond pad of the semiconductor device and the package lead. The bond wire can include a second wedge bond at the package lead. The package can also include a bond wire pad comprising Gold that extends longitudinally along and on the bond pad of the semiconductor device. The wedge bond of the bond wire can be positioned on the bond wire pad.

### BACKGROUND

Various types of packages are available for integrated semiconductor devices, including digital and analog integrated circuits, power transistor amplifiers, and related devices. The packages can both protect and secure the components and provide electrically conductive leads for electrical couplings to the integrated semiconductor devices. Example package types include surface mount, through-hole mount, flange mount, flat package, chip carrier, pin grid array, and chip-scale packages, and other packaging formats are known in the field. The type, size, lead style, structure, materials, and other characteristics of a package can be selected based on the type of components being housed within the package, as well as the application for the components. Certain packages can be more or less suitable for components used in high power and high frequency applications.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

An example semiconductor device package includes a semiconductor device having a bond pad, a package cover over the semiconductor device, and a bond wire of Copper that is electrically coupled to the bond pad of the semiconductor device. The bond wire includes a wedge bond at the bond pad. In some examples, the package can also include a package lead, and the bond wire can extend between and be electrically coupled to the bond pad of the semiconductor device and the package lead. The bond wire can include a second wedge bond at the package lead.

In other aspects, the semiconductor device package can also include a second semiconductor device having a second bond pad. The bond wire can extend between and be electrically coupled to the bond pad of the semiconductor device and the second bond pad of the second semiconductor device. The bond wire can include a second wedge bond at the second bond pad.

The bond wire can be formed of a Copper core and a plating layer over the Copper core. The bond wire can include a Copper core and a plating layer of Palladium over the Copper core in another example. The bond wire can include a Copper core and plating layers of Palladium and Gold over the Copper core in other examples.

In other aspects, the semiconductor device package can also include a bond wire pad that extends longitudinally along and on the bond pad of the semiconductor device. The bond wire pad can be formed of Gold in one example, and other metals can be relied upon. The wedge bond of the bond wire can be positioned on the bond wire pad in some cases. The bond wire can include the wedge bond on the bond wire pad and a second wedge bond at the package lead in other cases.

The semiconductor device package can also include a second semiconductor device having a second bond pad and a second bond wire pad. The second bond wire pad can extend longitudinally along and on the second bond pad of the second semiconductor device. The bond wire can extend between and be electrically coupled to the bond pad of the semiconductor device and the second bond pad on the second semiconductor device. The bond wire can include a wedge bond on the bond wire pad and a second wedge bond on the second bond wire pad.

Another example semiconductor device package includes a semiconductor device having a bond pad, a package cover over the semiconductor device, a package lead, and a bond wire including Copper that extends between and is electrically coupled to the bond pad of the semiconductor device and the package lead. The bond wire can include a first wedge bond at the bond pad and a second wedge bond at the package lead. The semiconductor device package can also include a second semiconductor device having a second bond pad, and a second bond wire including Copper that extends between and is electrically coupled to the bond pad of the semiconductor device and the second bond pad of the second semiconductor device. The second bond wire can include a first wedge bond at the bond pad and a second wedge bond at the second bond pad. The semiconductor device package can also include a bond wire pad formed of Gold that extends longitudinally along and on the bond pad of the semiconductor device. The first wedge bond of the bond wire can be positioned on the bond wire pad.

The semiconductor device package can also include a first bond wire pad including Gold that extends longitudinally along and on the bond pad of the semiconductor device, a second semiconductor device having a second bond pad, a second bond wire pad including Gold that extends longitudinally along and on the second bond pad of the second semiconductor device, and a second bond wire including Copper that extends between and is electrically coupled to the bond pad of the semiconductor device and the second bond pad of the second semiconductor device. The second bond wire can include a first wedge bond on the first bond wire pad and a second wedge bond on the second bond wire pad.

Another example semiconductor device package includes a semiconductor device having a bond pad, a package cover over the semiconductor device, a package lead, and a bond wire pad including Gold that extends longitudinally along and on the bond pad of the semiconductor device. The bond wire pad can be wedge bonded to the bond pad of the semiconductor device. The semiconductor device package can also include a bond wire including Copper that extends between and is electrically coupled to the bond pad of the semiconductor device and the package lead. The bond wire can include a first wedge bond on the bond wire pad and a second wedge bond at the package lead.

In other embodiments, a method of wedge bonding includes bonding a first segment of a bond wire to a bond pad of a semiconductor device using a wedge tool, bonding a second segment of the bond wire to a package lead using the wedge tool and, after bonding the second segment, changing an angle of extension of the bond wire. The method can also include, after changing the angle of extension, pulling and breaking the bond wire away from the package lead. The method can also include extending a first length of the bond wire from the bond pad and toward a package lead, before bonding a second segment of the bond wire to a package lead.

The bond wire can be formed of a Copper core and a plating layer over the Copper core. The bond wire can include a Copper core and a plating layer of Palladium over the Copper core in another example. The bond wire can include a Copper core and plating layers of Palladium and Gold over the Copper core in other examples.

Another example method of wedge bonding includes bonding a first segment of a bond wire to a bond wire pad using a wedge tool, where the bond wire pad is positioned on a bond pad of a semiconductor device, bonding a second segment of the bond wire to a package lead using the wedge tool, and changing an angle of extension of the bond wire after bonding the second segment. The method can also include, after changing the angle of extension, pulling and breaking the bond wire away from the package lead. The bond wire pad can be a Gold bond wire, and the bond wire can include Copper.

Another example method of wedge bonding includes bonding a first segment of a bond wire to a first bond wire pad using a wedge tool, where the bond wire pad is positioned on a first bond pad of a first semiconductor device, bonding a second segment of the bond wire to a second bond wire pad using the wedge tool, where the second bond wire pad is positioned on a second bond pad of a second semiconductor device, and changing an angle of extension of the bond wire after bonding the second segment. The bond wire pad can be a Gold bond wire, and the bond wire can include Copper.

In other aspects, changing the angle of extension of the bond wire can include changing the angle of extension of the bond wire from a first angle to a second angle. The method can also include, after changing the angle of extension, pulling the bond wire in a direction of the second angle and breaking the bond wire away from the package lead. Changing the angle of extension of the bond wire can also include changing the angle of extension of the bond wire from a first angle, a second angle, and back to the first angle. The method can also include, before changing the angle of extension of the bond wire, clamping the bond wire in position with respect to the wedge tool.

### BRIEF DESCRIPTION OF THE DRAWINGS

Aspects of the present disclosure can be better understood with reference to the following drawings. It is noted that the elements in the drawings are not necessarily to scale, with emphasis instead being placed upon clearly illustrating the principles of the embodiments. Among the figures of the drawings, like reference numerals designate similar or corresponding, but not necessarily the same, elements throughout the several views.

FIG. 1A illustrates a perspective view of an example semiconductor device package according to various embodiments described herein.

FIG. 1B illustrates the semiconductor device package shown in FIG. 1A with the cover removed according to various embodiments described herein.

FIG. 2 illustrates a top view of the semiconductor device package shown in FIG. 1A with the cover removed according to various embodiments described herein.

FIG. 3 illustrates the detail view of the semiconductor package designated AA in FIG. 2 according to various embodiments described herein.

FIGS. 4A-4D illustrate example steps in a method of wedge bonding according to various embodiments described herein.

FIG. 5A illustrates the detail view designated BB in FIG. 3 according to various embodiments described herein.

FIG. 5B illustrates a side view of the details shown in FIG. 5A according to various embodiments described herein.

FIG. 5C illustrates the detail view of the semiconductor package designated AA in FIG. 2, with bond pad wires, according to various embodiments described herein.

### DETAILED DESCRIPTION

A number of different device packages are available for electrical components, including semiconductor devices formed on semiconductor die. The packages can protect and secure the components, electrically connect or couple the components together using bond wires, provide electrically conductive leads for the components, provide heat dissipation, and serve other purposes. A range of different packages are known and available. Transistor outline packages (TOs), thermal enhancement packages (TEPACs), and other types packages can be used, as examples, to physically secure and electrically connect semiconductor devices and integrated circuits to printed circuit boards (PCBs). The type, size, lead style, structure, materials, and other characteristics of a device package can be selected based on the type of components packaged within it, the application for the components, and other factors.

Some packages are more suitable for components used in high power and high frequency applications, and the type, size, lead style, structure, materials, and other characteristics of packages can be selected and designed based on the types of components being housed within them, as well as the application for the components. Packages including air cavities are often used for high-power semiconductor devices, such as power transistors for high-power and high-frequency applications, because dielectric capacitances can be minimized in air cavity packages, among other benefits. Air cavity packages can include leads and be mounted on PCBs, in through holes of PCBs, and in other configurations.

In the context outlined above, semiconductor device packages including wire bond and wire bonding enhancements are described herein. An example semiconductor device package includes a semiconductor device having a bond pad, a package cover over the semiconductor device, and a bond wire including Copper that is electrically coupled to the bond pad of the semiconductor device. The bond wire includes a wedge bond at the bond pad. The package can also include a package lead, and the bond wire can extend between and be electrically coupled to the bond pad of the semiconductor device and the package lead. The bond wire can include a second wedge bond at the package lead. The package can also include a bond wire pad comprising Gold that extends longitudinally along and on the bond pad of the semiconductor device. The wedge bond of the bond wire can be positioned on the bond wire pad.

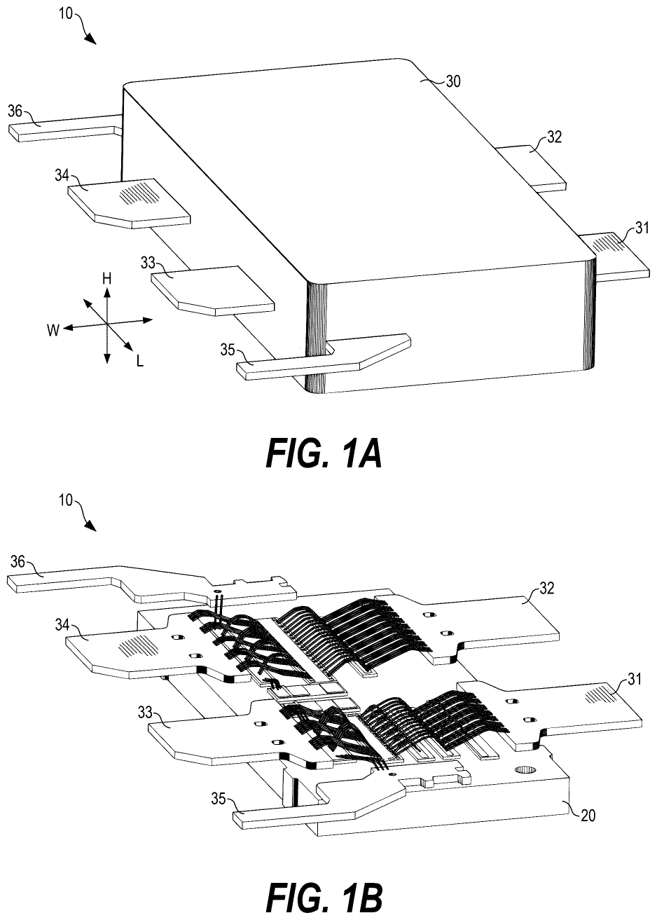

FIG. 1A illustrates a perspective view of an example semiconductor device package 10 (also “package 10”). FIG. 1B illustrates the package 10 shown in FIG. 1A with the cover of the package 10 omitted from view. The package 10 is depicted as a representative example. The package 10 is not drawn to scale, and other packages consistent with the concepts described herein can vary in shape and/or size as compared to that shown. For example, the length “L,” width “W,” height “H,” shape, and style of the package 10 can vary as compared to that shown among the embodiments. The style, size, number, and positions of the conductive leads of the package 10 can also vary as compared to that shown among the embodiments. The device package wire bonding and bond or bonding wire enhancements, as described herein, can be incorporated or practiced in connection with the package 10, but the concepts described herein are not limited to use with any particular type, size, lead style, or structure of package.

Referring between FIGS. 1A and 1B, the package 10 includes a flange 20, a package cover 30 (also “cover 10”) secured over the flange 20, and other components described below. The cover 30 is representative and can vary in size, shape, and style as compared to that shown in FIG. 1. The cover 30 can be embodied as a ring frame with a separate lid in one example, and the ring frame can be secured or otherwise adhered over the top surface of the flange. In that case, the cover 30 can accommodate an air cavity within the package 10, positioned over the flange 20 and under the cover 30 or the lid of the cover 30. The cover 30 can be secured over the flange 20 using any suitable means or methods, including epoxy or other adhesives, plastic welding, melting, and other approaches. The cover 30 can be secured over the flange 20 to create a hermetic (or near hermetic) seal for the package 10 in some cases. The package cover 30 can also be embodied as a full overmold. In that case, the package cover 30 can be molded over the top surface and the side surfaces of the flange 20, as well as over any components inside the package 10. The cover 30 can also accommodate an air cavity in the case of an overmold-type assembly of the package 10, and a lid can be relied upon to enclose the air cavity.

The cover 30 can be formed from plastics or polymers, such as liquid crystal polymers (LCPs) or polymer blends, with or without glass, carbon, or other reinforcements, among other materials. In other examples, the cover 30 can be formed using ceramic materials, metal, glass, or other suitable materials. The cover 30 is not limited to being formed from any particular material(s), however. The cover 30 can be formed using a range of suitable materials selected to provide protection (e.g., protection against temperatures, vibration, moisture, and other conditions) for the semiconductor devices in the package 10, mechanical strength, matching of the thermal expansion as compared to the flange 20 and other components of the package 10, and other relevant factors.

A number of semiconductors devices on semiconductor die can be secured within the package 10, as described below and shown in FIG. 1B. If the package 10 is implemented with an air cavity, then the components within the air cavity are not surrounded by (i.e., in contact with) package molding materials. The components will not be subject to any electrical effects due to the materials (e.g., parasitic capacitances, etc.) in that case. The concepts and embodiments described herein can be applied to other types of packages, such as full overmold packages without air cavities and other types of packages.

The package 10 also includes a number of conductive leads 31-36 (also “leads 31-36”), each of which extends from outside the cover 30, across or through at least a portion of the cover 30, and is exposed in part within the air cavity inside the package 10. The semiconductor devices in the package 10 can be electrically coupled, using bond wires (also “bond wires”) to the exposed portions of the conductive leads 31-36 within the package 10, as described in additional detail below. The conductive leads 31-36 can be formed from Tin (Sn), Copper (Cu), Aluminum (Al), Silver (Ag), Gold (Au), Zinc (Zn), other metals, and compositions thereof, and the conductive leads 31-36 can be plated with Ag, Au, Nickel (Ni), Palladium (Pd), or other metals using full plating, spot-plating or other techniques.

The flange 20 can be embodied as a conductive slug of metal, such as a slug formed from Cu, Al, Ag, Molybdenum (Mo), or other metals and can be plated in some cases. In some cases, the flange 20 can be embodied as a composite core of metal or metal alloy with other materials or particles, such as diamond particles, distributed in the metal or metal alloy. The flange 20 can serve as a conductive lead of the package 10 in some cases, as the flange 20 can be electrically conductive. Thus, a semiconductor device die including a metal layer on the bottom surface of the die can be electrically coupled to the top surface of the flange 20 within the package 10. The flange 20 can act as a type of lead for the package 10 in that case. In other cases, the flange 20 can act as a heat sink but not an electrical contact.

The package 10 is suitable for packaging RF power amplifiers for wireless communications applications, such as Doherty amplifiers, among other types of semiconductor devices. Doherty amplifiers include a main amplifier and a peaking amplifier, which can be implemented on two separate semiconductor die in some cases. The main and peaking amplifiers can be embodied as power transistors formed in Gallium Nitride (GaN) material(s), as one example, but the amplifiers within the package 10 are not limited to any particular type or technology of semiconductor materials. The main and peaking amplifiers operate in parallel on an input RF signal, which is divided into parallel circuit branches by a power coupler. Outputs from the main and peaking amplifiers and are subsequently combined into a single RF output.

When the package 10 includes power amplifiers for a Doherty amplifier, the leads 31 and 32 can be electrically coupled to the gate terminals of the main and peaking power amplifiers, respectively, using bond wires. Thus, the leads 31 and 32 can be referred to as input leads. The leads 33 and 34 can be electrically coupled to the drain terminals of the main and peaking power amplifiers, respectively, using bond wires. Thus, the leads 33 and 34 can be referred to as output leads. The source terminals of the main and peaking power amplifiers can be electrically coupled to the flange 20. Other connections among semiconductor devices within the package 10 are within the scope of the embodiments.

Along with the main and peaking power amplifiers, the package 10 can also include one or more input matching networks, output matching networks, biasing networks, and combinations of such networks (collectively “matching networks”) for the main and peaking power amplifiers. The input matching, output matching, and biasing networks can be embodied as networks of reactive components (e.g., “L,” “C,” and “LC” networks), including combinations of one or more capacitors and inductors. The components of the matching networks can also be implemented one or more semiconductor die within the package 10.

In the package 10, the conductive leads 35 and 36 are electrically coupled to the output matching networks of the main and peaking amplifiers using bond wires. The conductive leads 35 and 36 facilitate the use of off-package decoupling capacitors to meet certain operating specifications. The conductive leads 35 and 36 can be referred to as decoupling or video bandwidth enhancement leads or terminals for that reason.

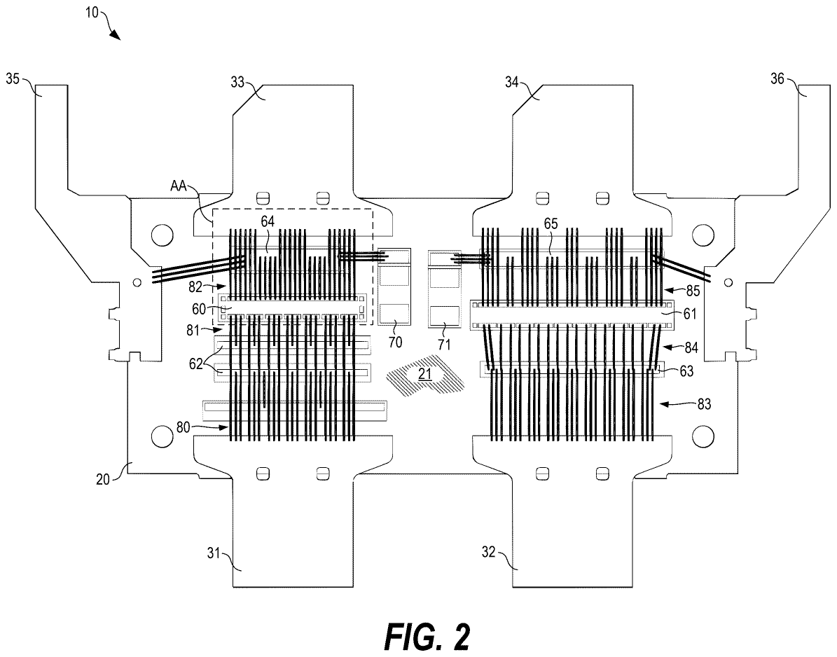

FIG. 2 illustrates a top view of the semiconductor device package 10 shown in FIG. 1A with the cover 30 removed. A number of semiconductor die, including power transistor amplifiers, matching networks, and other circuit elements are attached and secured to the top surface 21 of the flange 20 in the example shown. The active devices, passive devices, and other components on the semiconductor die are electrically coupled among each other and to the conductive leads 31-36 by bond wires, as described in further detail below. The arrangement of semiconductor die and bond wires is depicted as a representative example in FIG. 2. Other arrangements are within the scope of the embodiments. Additional components can also be added, and one or more of the semiconductor die can also be omitted in some cases.

FIG. 2 illustrates a semiconductor die 60 for a first or main power amplifier transistor (also “amplifier 60”), a semiconductor die 61 for a second or peaking power amplifier transistor 61 (also “amplifier 61”), a semiconductor die 62 for a first input matching network (also “input matching network 62”), a semiconductor die 63 for a second input matching network (also “input matching network 63”), a semiconductor die 64 for a first output matching network (also “output matching network 64”), and a semiconductor die 65 for a second output matching network (also “output matching network 65”), among possibly others. FIG. 2 also illustrates semiconductor die 70 and 71 for termination capacitors (also “termination capacitors 70 and 71”).

The amplifiers 60 and 61 can each be embodied as a power transistor formed in GaN materials on a semiconductor die or suitable substrate. Each of the matching networks 62-65 can be embodied as a network of reactive components, such as an arrangement of inductors and capacitors, implemented on a semiconductor die or suitable substrate. The matching networks 62-65 can also include resistors, transmission lines, and related components for matching networks in some cases. The termination capacitors 70 and 71 can be embodied as capacitors implemented on a semiconductor die or suitable substrate. The termination capacitors 70 and 71 are electrically coupled to and may be considered components of the output matching networks 64 and 65 in the example shown.

The matching networks 62-65 and termination capacitors 70 and 71 can be relied upon for harmonic termination, input impedance matching, output impedance matching, memory effect control, video bandwidth control, and to tailor other operating aspects of the amplifiers 60 and 61. Depending on the needs for impedance matching, memory effect control, etc., one or more of the input matching networks 62 and 63, output matching networks 64 and 65, and termination capacitors 70 and 71 can be omitted in some cases.

As shown in FIG. 2, the amplifiers 60 and 61, matching networks 62-65, and termination capacitors 70 and 71 can be mounted to the top surface 21 of the flange 20 (see also FIG. 1B for the flange 20). The bottom surfaces of certain semiconductor die can be electrically coupled to the top surface 21 of flange 20 itself. For example, the bottom surfaces of the amplifiers 60 and 61 can be electrically coupled to the top surface 21 of the flange 20. The flange 20 can act as a source contact or lead for the amplifiers 60 and 61 in that case. The matching networks 62-65 and termination capacitors 70-73 can also be electrically coupled to the flange 20 in a similar way, as needed. Each semiconductor die can be secured to the top surface 21 of the flange 20 using thermal epoxy, solder, solder preforms, sintered die attach, or other suitable means.

The amplifiers 60 and 61, matching networks 62-65, and termination capacitors 70 and 71 are also electrically coupled to the conductive leads 31-36 of the package 10 and each other using bond wires in the example shown. As examples, the bond wires 80 electrically couple the input conductive lead 31 with the input matching network 62. The bond wires 80 also electrically couple the input conductive lead 31 with the amplifier 60. The bond wires 81 electrically couple the input matching network 62 with the amplifier 60. The bond wires 82 electrically couple the amplifier 60 with the output matching network 64 and the output conductive lead 33. The bond wires 83 electrically couple the input conductive lead 32 with the input matching network 63. The bond wires 84 electrically couple the input matching network 63 with the amplifier 61. The bond wires 85 electrically coupled the amplifier 61 with the output matching network 65. Other bond wires in the package 10 can facilitate other electrical connections among components, and the bond wires 80-85 are presented as examples.

Bond wires, such as the bond wires 80-85, can be embodied by conductive metal or metal materials, and Gold bond wires are common. Bond wires can be formed using a range of different materials, however, and Silver, Aluminum, Copper, and other metals can be used to form bond wires. Bond wires can also be formed from metal alloys and with one or more metal plating layers in some cases. Bond wires can also be formed to a range of different diameters or thicknesses.

A number of different wire bonding machines and approaches are available for placing and electrically coupling the bond wires 80-85 to bonding pads of the semiconductor die 60-65 and surfaces of the conductive leads 31-36, among other locations. Wire bonding machines typically use ultrasonic, thermosonic, or thermocompression bonding, which encompass the use of pressure, vibration, heat, or some combination thereof to form metallurgic bonds between bond wires and the bonding pads and other surfaces being electrically coupled with each other. Ball bonding and wedge bonding machines use different approaches to electrically couple bond wires, and the selection of the appropriate type of wire bonding machine and bond wire can be important depending on the application for use, operating specifications, and other design concerns.

Copper bond wires can offer some advantages as compared to Gold bond wires. Copper bond wires are relatively cheaper, have lower resistance, higher melting point, and exhibit higher thermal conductivity than Gold bond wires, among other benefits. The oxidation of Copper bond wires can also be mitigated by plating the Copper with Palladium or another plating metal. In another aspect, wedge bonding can offer advantages as compared to ball bonding. For example, the pitch or spacing between bond wires can be increased using wedge bonding, because the relatively large ball bonds are avoided through wedge bonding. However, wedge bonding machines and approaches can be difficult to use and implement with Copper bond wires, among other bond wires formed of certain materials, because of the mechanical strength (e.g., shear strength, elastic modulus, etc.) of Copper bond wires.

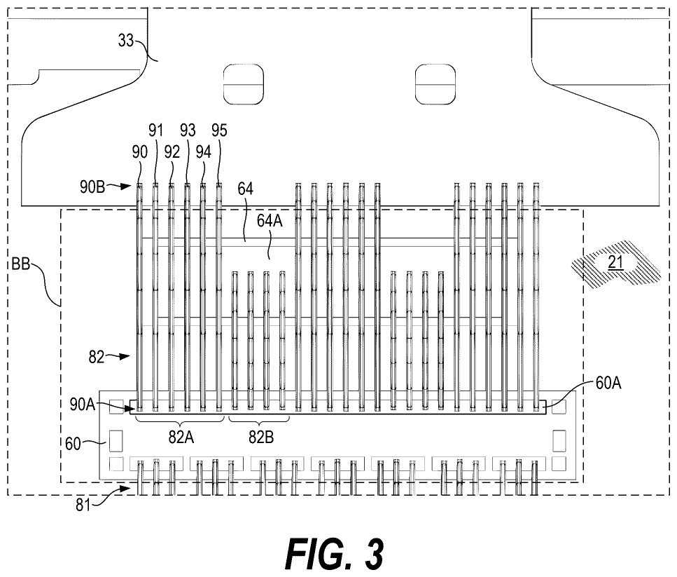

FIG. 3 illustrates the detail view of the semiconductor package designated AA in FIG. 2. FIG. 3 shows top surface 21 of the flange 20, the amplifier 60, the output conductive lead 33, the output matching network 64, and the bond wires 82. A first subset 82A of the bond wires 82 is electrically coupled between a bond pad 60A of the amplifier 60 and the output conductive lead 33. More particularly, one end of each bond wire among the first subset 82A of the bond wires 82 is electrically coupled to the bond pad 60A of the amplifier 60. Another end of each bond wire among the first subset 82A of the bond wires 82 is electrically coupled to the output conductive lead 33. A second subset 82B of the bond wires 82 is electrically coupled between the bond pad 60A of the amplifier 60 and the bond pad 64A of the output matching network 64. More particularly, one end of each bond wire among the second subset 82B of the bond wires 82 is electrically coupled to the bond pad 60A of the amplifier 60. Another end of each bond wire among the second subset 82B of the bond wires 82 is electrically coupled to the bond pad 64A of the output matching network 64.

The bond wires 82 in the package 10 are placed and electrically coupled at each end using a wedge bonding machine. Thus, there are no ball bonds at either end of any of the bond wires 82. The other bond wires 80, 81, and 83-85 (see FIG. 2) are also placed and electrically coupled at each end using a wedge bonding machine without ball bonds. The bond wires 80-85 are placed and electrically coupled among the components in the package 10 by a wedge bonding machine using a sequence of steps or movements that facilitate the use of copper bond wires, as described in further detail below.

The use of wedge bonding to place the bond wires 80-85 facilitates the use of a tighter or denser bond wire pitch. For example, the number of bond wires in the first subset 82A of the bond wires 82 can be increased in the space shown in FIG. 2. The number of bond wires can be increased using wedge bonding because the relatively large ball bonds at ends of the bond wires 82 are not needed or used. Decreasing the pitch between and increasing the number of bond wires in the package 10 can have benefits, such as a lower overall resistance through the bond wires, better heat dissipation through the bond wires, and other benefits. Additionally, the overall size and surface area of the bond pad 60A can be reduced, because the bond pad 60A does not need to accommodate the relatively large ball bonds at ends of the bond wires 82.

The bond wires 80-85 are formed of, and may consist only of, copper in one embodiment. The bond wires 80-85 can also be formed of a copper core and include one or more plating or outer layers over the copper core some cases. The plating layer can include a plating layer of palladium, chromium, gold, or tin, as examples, and other suitable plating layers can also be relied upon. The bond wires 80-85 can be formed of a copper core with a plating layer of palladium in one preferred embodiment. The bond wires 80-85 can also be formed of a copper core with a first plating layer of palladium and a second, flashed (e.g., relatively thinner) layer of gold in another preferred embodiment. The bond wires 80-85 are not limited to any particular composition of metal(s), any particular size (e.g., length or thickness), or limited to other characteristics, however.

Although Gold bond wires are very common, Copper bond wires can offer some advantages. Copper bond wires are relatively cheaper, have lower resistance, higher melting point, and exhibit higher thermal conductivity than Gold bond wires, among other benefits. The oxidation of Copper bond wires can also be mitigated by the use of plating metal(s) over the Copper wire core. In another aspect, wedge bonding can offer advantages as compared to ball bonding. For example, the pitch or spacing between bond wires can be increased using wedge bonding, because the relatively large ball bonds are avoided through wedge bonding.

Referring to FIG. 3 as an example, the first subset 82A of the bond wires 82 is electrically coupled between a bond pad 60A of the amplifier 60 and the output conductive lead 33. The first subset 82A includes bond wires 90-95. A wedge bonding machine can first place one end 90A of the bond wire 90 on the bond pad 60A, extend the bond wire 90 towards the output conductive lead 33, and then place another end 90B of the bond wire 90 on the output conductive lead 33. The ends 90A and 90B of the bond wire 90 are electrically and mechanically coupled to the bond pad 60A and the output conductive lead 33, respectively, using pressure, ultrasonic vibration, the use of heat in thermocompression, or some combination thereof by the wedge bonding machine. The other bond wires 91-95, among others in the package 10, can be placed and coupled in a similar way using the wedge bonding machine.

If the bond wire 90 is formed of a relatively soft or malleable metal, such as gold, the act of bonding the end 90B of the bond wire 90 to the output conductive lead 33 can also sever or break the bond wire 90 at that location. Then, the wedge bonding machine can place the bond wire 91, among others, in repeat wire bonding steps. However, if the bond wire 90 is formed of a relatively harder and stronger metal, such as copper, the thermocompression of the end 90B of the bond wire 90 to the output conductive lead 33 may not sever or break the bond wire 90 at the bonding location on the output conductive lead 33. According to aspects of the embodiments, wedge bonding machines can be programmed to make certain movements, pull in certain directions, and take other actions to break and sever bond wires, including copper and other bond wires having relatively high strength. The movements and actions of the wedge bonding machines can facilitate the use of a wider range of bond wires of different materials, increase the density or number of bond wires in semiconductor packages, and provide other benefits.

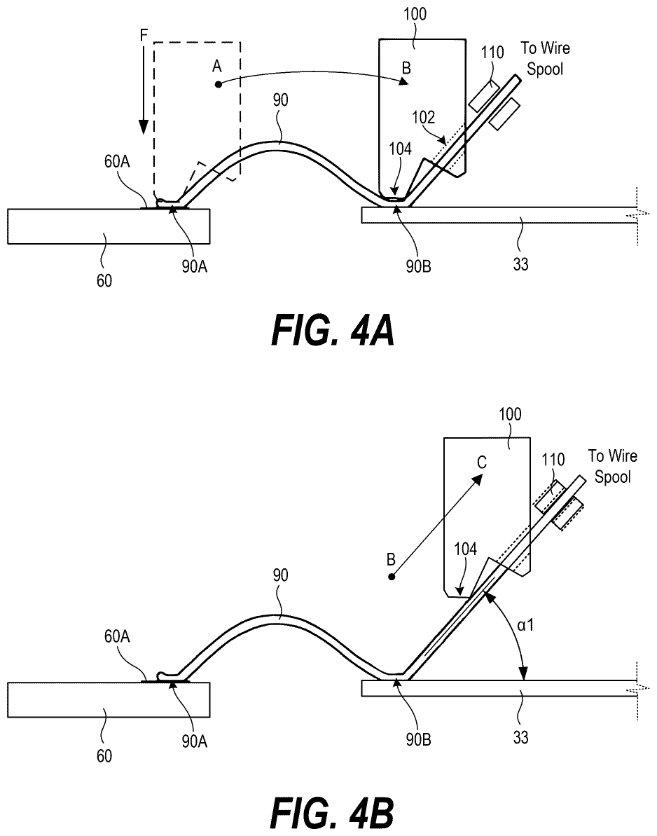

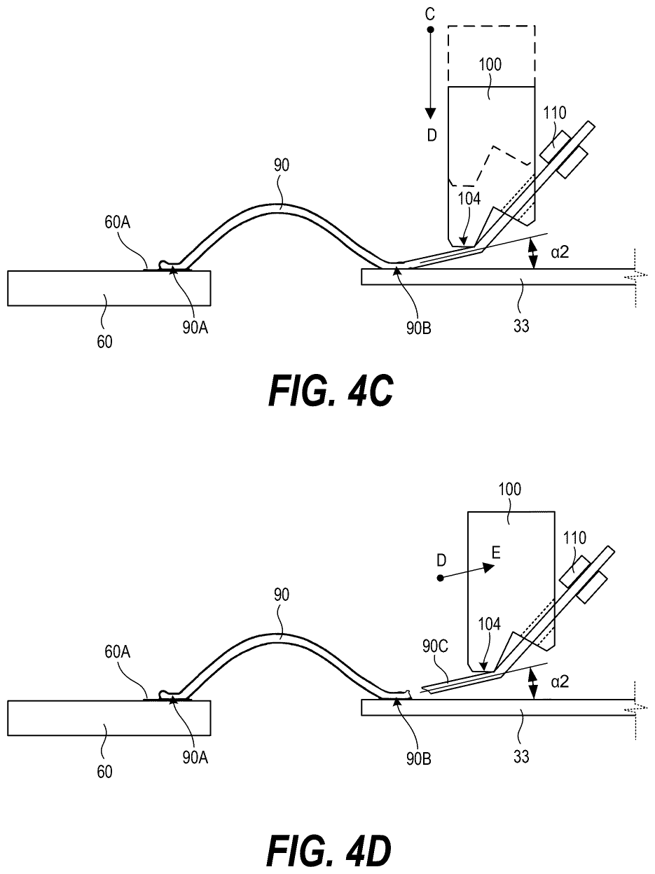

FIGS. 4A-4D illustrate example steps in a method of wedge bonding according to various embodiments described herein. The steps shown in FIGS. 4A-4D can be useful when using wedge bonding machines and approaches with bond wires formed of metal having relatively high strength, such as Copper, as one example. The steps can also be useful when using bond wires formed from different types of metal(s), however, and the concepts described herein can be applicable to solving problems beyond those described herein. The steps shown in FIGS. 4A-4D are representative. The steps show an example of bonding both ends of the bond wire 90 shown in FIG. 3, and the steps can also be used to bond other bond wires in the package 10. As compared to that shown and described below, one or more of the steps can be can be performed repeatedly, in alternative sequences, in different orders, and in other ways.

FIG. 4A depicts a side view of the amplifier 60, the output conductive lead 33, the output matching network 64, and the bond wire 90. A wedge tool 100 of a wedge bonding machine is also shown in FIG. 4A, along with a wire clamp 110 of the wedge bonding machine. The wedge tool 100 includes an opening or aperture 102. The distal end of a bond wire, extending form a spool of wire, passes through the opening or aperture 102. Segments of the bond wire can be wedged and pressed against surfaces by the wedge nose 104 of the wedge tool 100, as described below. A combination of ultrasonic vibration, pressure or force, and possibly heat can be applied with the wedge tool 100, to bond segments of the bond wire to bond pads of semiconductor die, package leads, and other surfaces. Wedge bonds can be formed between bond wires and bond pads, package leads, and other surfaces using the wedge tool 100 in that way. The wedge tool 100 can also move or reposition itself after wedge bonds are formed, extending lengths of the bond wire from the spool, and forming additional wedge bonds. An example sequence of steps for placing and electrically coupling the bond wire 90 between the amplifier 60 and the output conductive lead 33 is described below.

Starting at the position “A” in FIG. 4A, the method includes bonding a first segment of the bond wire 90 to the bond pad 60A of the amplifier 60 using the wedge tool 100. The wedge tool 100 can clamp the segment or end 90A of the bond wire 90 to the bond pad 60A using a combination of ultrasonic vibration, pressure or downward force in the direction “F,” and possibly heat applied through the wedge tool 100. More particularly, the wedge nose 104 of the wedge tool 100 presses the end 90A of the bond wire 90 to the bond pad 60A and can apply ultrasonic vibration to form a wedge bond between them. Mechanical and electrical contact is made between the end 90A of the bond wire 90 and the bond pad 60A using the wedge tool 100 in this process step, and the end 90A of the bond wire 90 becomes wedge bonded (e.g., a metallurgical bond is formed) with the bond pad 60A.

Between the positions “A” and “B” in FIG. 4A, the method includes extending a length of the bond wire 90 from the bond pad 60A and toward the output conductive lead 33. The wedge tool 100 can move both up and to the right of the page of FIG. 4A, creating a type of raised, partial loop or bend in the bond wire 90 between the bond pad 60A and the output conductive lead 33.

Still referring to FIG. 4B, the method can include bonding a second segment of the bond wire 90 to the surface of the output conductive lead 33 using the wedge tool 100. In the example shown, the wedge tool 100 can clamp the segment or end 90B of the bond wire 90 to the surface of the output conductive lead 33 using a combination of ultrasonic vibration, pressure or downward force, and possibly heat applied through the wedge tool 100. Mechanical and electrical contact is made between the end 90B of the bond wire 90 and the output conductive lead 33 using the wedge tool 100 in this process step, and the end 90B of the bond wire 90 becomes wedge bonded with the output conductive lead 33.

Turning to FIG. 4B, the method includes extending a second length of the bond wire 90 at an angle α1 of extension, measured between the longitudinal axis of the bond wire 90 and the surface of the output conductive lead 33. The length of extension between the positions “B” and “C” is representative in FIG. 4B, and the bond wire 90 can be extended to any suitable length. The method then includes clamping the bond wire 90 with respect to the wedge tool 100, using the wire clamp 110. The wire clamp 110 can clamp against and hold the bond wire 90 in position with respect to the wedge tool 100. Once clamped, the position of the bond wire 90 can be maintained with respect to the wedge tool 100, without pulling more of the bond wire 90 from the wire spool, even when the wedge tool 100 moves.

Turning to FIG. 4C, the method includes changing the angle of extension of the bond wire 90 from the first angle α1 to the second angle α2 using the wedge tool 100. To change the angle, the wedge tool 100 is moved from the position “C” to the position “D,” as shown. As part of that movement, the angle of extension of the bond wire 90, measured between the longitudinal axis of the bond wire 90 from the end 90B and the surface of the output conductive lead 33, changes from the first angle α1 to the second angle α2. The second angle α2 is smaller than the first angle α1. As an example, the first angle α1 can be between 60-35°, and the second angle α1 can be between 25-15°. However, a range of different angles α1 and α2 can be relied upon. The movement shown in FIG. 4C helps to deform the material from which the bond wire 90 is formed, particularly at a position just past the end 90B of the bond wire 90, at or nearly at the vertex of the angles α1 and α2. The movement will cause the bond wire 90 to deform at that vertex point and, ultimately, weaken the bond wire 90 (e.g., reduce the yield strength) at that point. The angle of extension of the bond wire 90 can also be changed from α2 to α1 in other examples.

Turning to FIG. 4D, the method includes pulling the bond wire 90 away from the output conductive lead 33 in a direction tracking the second angle α2 using the wedge tool 100. This step will sever or break the bond wire 90 away from the remainder of the bond wire 90C held by the wedge tool 100, as shown in FIG. 4D. The process can then repeat to place additional bond wires having wedge bonds.

The process shown among FIGS. 4A-4D can be useful for wedge bonding bond wires formed of metal having relatively high strength, such as Copper. The movement shown in FIG. 4C, which changes the angle of extension of the bond wire 90 from the first angle α1 to the second angle α2, can weaken the yield strength of Copper bond wires, as well as bond wires formed from other metals. It may be unnecessary to change the angle of extension for bond wires formed from Gold, because breaking the bonded wire away. However, changing the angle of extension can be helpful (and necessary in some cases) to avoid breaking the bond between the bond wire 90 and the output conductive lead 33 at the end 90B of the bond wire 90, when the bond wire 90 is separated away from the wire spool.

In some cases, the method can include a repeated change of the angle of extension of the bond wire 90 between the angles α1 and α2, among possibly other angles, including third α3, fourth α4, and possibly more angles. As one example, the angle of extension of the bond wire 90 can be changed from α1, to α2, and back to α1. The method can then include pulling the bond wire 90 away from the output conductive lead 33 in a direction tracking the angle α1 using the wedge tool 100. As another example, the angle of extension of the bond wire 90 can be changed from α1, to α2, to α1, and back to α2. The method can then include pulling the bond wire 90 away from the output conductive lead 33 in a direction tracking the angle α2 using the wedge tool 100. Any number of bends or angle changes can be relied upon, and angles of extension greater than α1, less than α2, and between α1 and α2 can also be used.

The process shown among FIGS. 4A-4D can also be applied between a bond pad of one semiconductor device, at one end of a bond wire, and another bond pad of another semiconductor device, at another end of the bond wire. For example, the process can be applied to bond the end 90A of the bond wire 90 to the bond pad 60A of the amplifier 60, at one end, and to bond the end 90B of the bond wire 90 to the bond pad 64A of the output matching network 64, at another end of the bond wire 90.

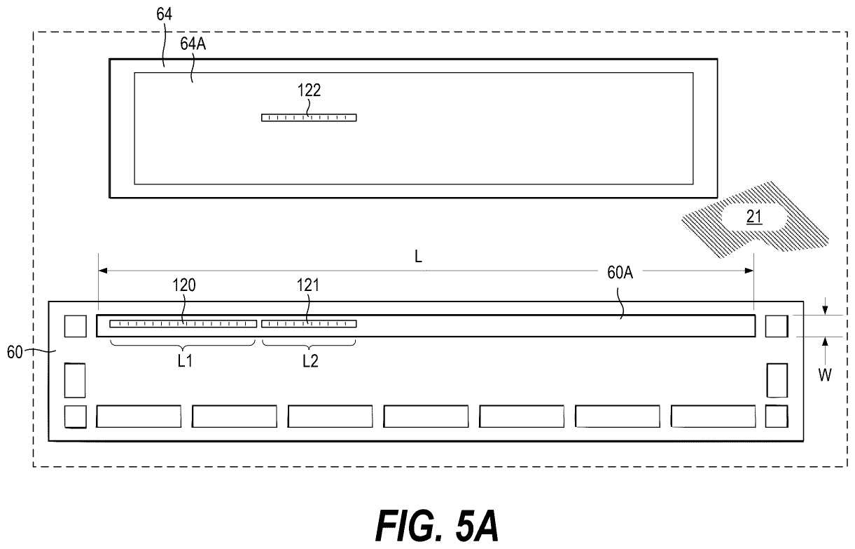

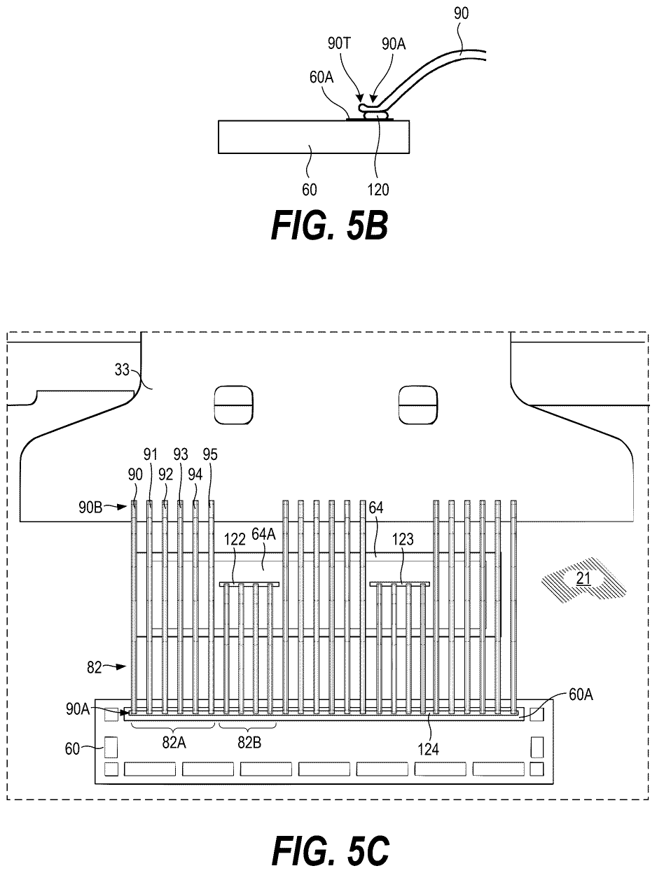

The process shown among FIGS. 4A-4D can also be applied to or on bond wire pads, as described herein, including those shown and described below with reference to FIGS. 5A-5C. For example, the wedge tool 100 can bond the end 90A of the bond wire 90 to the bond wire pad 120, as described below, and can apply ultrasonic vibration to form a wedge bond of the bond wire 90 to the bond wire pad 120. The process can also be applied between a first bond wire pads on a first bond pad of a first semiconductor device, at one end of a bond wire, and another bond wire pad on a second bond pad of a second semiconductor device, at another end of the bond wire.

FIG. 5A illustrates the detail view designated BB in FIG. 3. FIG. 5A shows the top surface 21 of the flange 20, the amplifier 60, and the output matching network 64 of the package 10. The bond pad 60A of the amplifier 60 and the bond pad 64A of the output matching network 64 are also shown. Bond wires of the package 10 are omitted from view in FIG. 5A. FIG. 5B illustrates a side view of the amplifier 60 shown in FIG. 5A. FIGS. 5A and 5B also illustrate bond wire pads, which are described below.

FIG. 5A illustrates bond wire pads 120-122. The bond wire pads 120 and 121 are positioned and bonded on the bond pad 60A of the amplifier 60. The bond wire pad 122 is positioned and bonded on the bond pad 64A of the output matching network 64. The bond wire pads 120 and 121 are bond wires that are bonded longitudinally along the length “L” of the bond pad 60A, using a wedge bonding approach. To be distinguished from the bond wires 80-85, which electrically couple different components in the package 10 among each other, the bond wire pads 120 and 121 do not electrically couple different components to each other. Instead, the bond wire pads 120 and 121 provide a type of elevated surface, or elevated pad, upon which a wedge bond for another bond wire can be placed. The bond wire pads 120 and 121 can be formed from a relatively soft and malleable metal, such as Gold, to provide a padding layer. The bond wire pad 122 is also bonded longitudinally along a length of the bond pad 64A, using a wedge bonding approach. The bond wire pad 122 can also be formed from a relatively soft and malleable metal, such as Gold, to provide a padding layer.

The bond wire pads 120 and 121 are wedge bonded to the bond pad 60A without any loops or air gaps. For example, along the length “L1” of the bond wire pad 120, the bond wire pad 120 can be wedge bonded to the bond pad 60A at multiple locations, and the bond wire pad 120 can contact the bond pad 60A along the full length of the “L1” of the bond wire pad 120. In a similar way, the bond wire pad 121 can be wedge bonded to the bond pad 60A at multiple locations along the length “L2,” and the bond wire pad 121 can contact the bond pad 60A along the full length of the “L2” of the bond wire pad 121. The bond wire pads 120 and 121 can be wedge bonded any number of times, and typically closely together, along the lengths “L1 and “L2.” Thus, the methods described herein can also include wedge bonding one or more bond wire pads to one or more bond pads of semiconductor device(s).

FIG. 5B illustrates a side view of the bond wire pad 120 and the amplifier 60 shown in FIG. 5A, as well as the bond wire 90. The bond wire pad 120 is positioned on the top surface of the bond pad 60A of the amplifier 60. The bond wire 90 is wedge bonded on or onto (and over) the bond wire pad 120. The bond wire pad 120 thus provides a type of elevated surface, or elevated pad, upon which a wedge bond for the bond wire 90 can be placed. A wedge tool, such as the wedge tool 100 shown in FIGS. 4A-4D, can clamp the segment or end 90A of the bond wire 90 to the bond wire pad 120 using a combination of ultrasonic vibration, pressure or downward force, and possibly heat.

The bond wire pad 120, among others in the package 10, can provide a number of benefits. The bond wire pad 120 can provide an elevated surface upon which wedge bonds can be formed. Thus, the tail 90T of the bond wire 90 can be raised up and away from the top surface of the amplifier 60. With the tail 90T raised, the overall size (e.g., see “L” and “W” in FIG. 5A) of the bond pad 60A of the amplifier 60 can be reduced. The bond wire pad 120 can also provide a type of pad or cushion upon which to form wedge bonds, possibly avoiding damage to the bond pad 60A, the amplifier 60, or both.

Referring back to FIG. 5A, the package 10 can include one, two, or more bond wire pads on a bond pad of a semiconductor device die. Two bond wire pads 120 and 121 are shown on the bond pad 60A of the amplifier 60, as one example. The bond wire pad 120 is sized in length to accommodate the span of the first subset 82A of the bond wires 82 (see FIG. 3), and the bond wire pad 121 is sized for the second subset 82B of the bond wires 82. However, bond pad wires of different sizes (e.g., lengths) can be used, and additional bond pad wires can also be placed along the bond pad 60A. As another example, one bond wire pad 122 is shown on the bond pad 64A of the output matching network 64, but additional bond wire pads can be placed on the bond pad 64A. In other cases, a single, longer bond wire pad can be placed along the bond pad 60A of the amplifier 60. A single, longer bond wire pad can also be placed along the bond pad 64A of the output matching network 64.

FIG. 5C illustrates the detail view of the semiconductor package designated AA in FIG. 2, with bond pad wires 122-124. The example shown in FIG. 5C is similar to that shown in FIG. 5B, but the bond wire pads 120 and 121 have been replaced by a single bond wire pad 124 on the bond pad 60A of the amplifier 60. The bond wire pad 124 extends substantially the full length “L” (see FIG. 5A) of the bond pad 60A. Two bond wire pads 122 and 123 are also positioned on the bond pad 64A of the output matching network 64, rather than only the bond wire pad 122. In the example shown in FIG. 5C, each bond wire in the first subset 82A of bond wires 82 includes a wedge bond on the bond wire pad 124 at one end and a wedge bond on the output conductive lead 33 at another end. Each bond wire in the second subset 82B of bond wires 82 includes a wedge bond on the bond wire pad 124 at one end and a wedge bond on the bond wire pad 122 at another end.

FIGS. 5A-5C depict examples of wedge-on-wedge bonding techniques that can be incorporated into the package 10. The bond pad wires shown in FIGS. 5A-5C can be formed of a first, relatively softer or more malleable metal, and the other bond wires in the package 10 can be formed from a second, more rigid or higher strength metal. As one example, the bond pad wires in the package 10 can be formed from Gold and the bond wires in the package 10 can be formed from Copper or a Copper core with one or more plating metal layers, such as Palladium and Gold plating metal layers. Variations on the package 10, the semiconductor die secured within the package 10, and the arrangements of the bond wires and bond wire pads are within the scope of the embodiments. The concepts described herein can also be extended to use with other types of packages.

Power transistors formed on semiconductor die can be packaged using the embodiments described herein. Among other types, the transistors described herein can be formed as high electron mobility transistors (HEMTs), pseudomorphic high-electron mobility transistors (pHEMTs), metamorphic high-electron mobility transistors (mHEMTs), laterally diffused metal oxide semiconductor transistors (LDMOS), metal-insulator-semiconductor field effect transistors (MISFETs or MISHFETs), metal-oxide-semiconductor field effect transistors (MOSFETs).

The power transistors described herein can be formed using a number of different semiconductor materials and semiconductor manufacturing processes. Example semiconductor materials include the group IV elemental semiconductor materials, including Silicon (Si) and Germanium (Ge), compounds thereof, and the group III elemental semiconductor materials, including Al, Gallium (Ga), Indium (In), and compounds thereof. Semiconductor transistor amplifiers can be constructed from group III-V direct bandgap semiconductor technologies, in certain cases, as the higher bandgaps and electron mobility provided by those devices can lead to higher electron velocity and breakdown voltages, among other benefits. Thus, in some examples, the concepts can be applied to group III-V direct bandgap active semiconductor devices, such as III-Nitride material devices (Aluminum (Al)—, Gallium (Ga)—, Indium (In)—, and their alloys (AlGaIn) based Nitrides), GaAs, InP, InGaP, AlGaAs, etc. devices. However, the principles and concepts can also be applied to transistors and other active devices formed from other semiconductor materials.

As used herein, the term “III-Nitride material(s)” or “Gallium Nitride material(s)” refers to any Group III element-nitride compound. Non-limiting examples of III-nitride materials include Boron Nitride (BN), Aluminum Nitride (AlN), Gallium Nitride (GaN), Indium Nitride (InN), and Thallium Nitride (TIN), as well as any alloys including Group III elements and Group V elements, such as Aluminum Gallium Nitride (Alₓ Ga₍₁₋ₓ₎ N), Indium Gallium Nitride (In_{y} Ga_{(1-y)} N), Aluminum Indium Gallium Nitride (Alₓ In_{y} Ga_{(1-x-y)} N), Gallium Arsenide Phosphide nitride (GaASₐ P_{b} N_{(1-a-b)}), Aluminum Indium Gallium Arsenide Phosphide Nitride (Alₓ In_{y} Ga_{(1-x-y)} ASₐ P_{b} N_{(1-a-b)}), among others. Typically, when present, Arsenic and/or Phosphorous are at low concentrations (e.g., less than 5 weight percent). The term “Gallium Nitride” or GaN semiconductor refers directly to gallium nitride, exclusive of its alloys.

According to certain embodiments, the substrates of the semiconductor devices described herein can include Silicon (Si) (i.e., a substrate containing the Si in any form). Examples of substrates comprising Si that can be used in various embodiments include, but are not limited to, SiC substrates, bulk Si wafers, Si-on-insulator (SOI) substrates, Silicon-on-sapphire (SOS) substrates, and separation by implantation of oxygen (SIMOX) substrates, among others. Suitable Silicon substrates also include composite substrates that include a Si wafer bonded to another material such as diamond, AlN, SiC, or other polycrystalline materials. Silicon substrates having different crystallographic orientations can be used, though single crystal silicon substrates can be preferred in certain, but not necessarily all, embodiments. In some embodiments, Silicon (111) substrates are used. A III-Nitride or GaN transistor can be a III-Nitride heterostructure FET (III-N HFET), a metal-insulator-semiconductor FET (MISFET or MISHFET), such as a metal-oxide-semiconductor FET (MOSFET). Alternatively, when implemented as an HFET, III-Nitride transistor can be a HEMT configured to produce a 2DEG.

The features, structures, and characteristics described above may be combined in one or more embodiments in any suitable manner, and the features discussed in the various embodiments are interchangeable in many cases. Although relative terms such as “on,” “below,” “upper,” “lower,” “top,” “bottom,” “right,” and “left” may be used to describe the relative spatial relationships of certain structural features, these terms are used for convenience only, as a direction in the examples. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. are used only as labels, rather than a limitation for a number of the objects.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be interpreted to encompass modifications and equivalent structures.

1. A semiconductor device package, comprising:
a semiconductor device comprising a bond pad;
a package cover over the semiconductor device; and
a bond wire comprising Copper that extends and is electrically coupled to the bond pad of the semiconductor device, the bond wire comprising a wedge bond at the bond pad of the semiconductor device.

2. The semiconductor device package according to claim 1, further comprising:
a package lead, wherein:
the bond wire extends between and is electrically coupled to the bond pad of the semiconductor device and the package lead; and
the bond wire comprises the wedge bond at the bond pad and a second wedge bond at the package lead.

3. The semiconductor device package according to claim 1, further comprising:
a second semiconductor device comprising a second bond pad, wherein:
the bond wire extends between and is electrically coupled to the bond pad of the semiconductor device and the second bond pad of the second semiconductor device; and
the bond wire comprises the wedge bond at the bond pad and a second wedge bond at the second bond pad.

4. The semiconductor device package according to claim 1, wherein the bond wire comprises a Copper core and a plating layer over the Copper core.

5. The semiconductor device package according to claim 1, wherein the bond wire comprises a Copper core and a plating layer of Palladium over the Copper core.

6. The semiconductor device package according to claim 1, wherein the bond wire comprises a Copper core and plating layers of Palladium and Gold over the Copper core.

7. The semiconductor device package according to claim 1, further comprising a bond wire pad that extends longitudinally along and on the bond pad of the semiconductor device.

8. The semiconductor device package according to claim 7, wherein the bond wire pad comprises Gold.

9. The semiconductor device package according to claim 7, wherein the wedge bond of the bond wire is on the bond wire pad.

10. The semiconductor device package according to claim 7, further comprising:
a package lead, wherein:
the bond wire extends between and is electrically coupled to the bond pad of the semiconductor device and the package lead; and
the bond wire comprises the wedge bond on the bond wire pad and a second wedge bond at the package lead.

11. The semiconductor device package according to claim 7, further comprising:
a second semiconductor device comprising a second bond pad; and
a second bond wire pad that extends longitudinally along and on the second bond pad of the second semiconductor device, wherein:
the bond wire extends between and is electrically coupled to the bond pad of the semiconductor device and the second bond pad on the second semiconductor device; and
the bond wire comprises the wedge bond on the bond wire pad and a second wedge bond on the second bond wire pad.

12. A semiconductor device package, comprising:
a semiconductor device comprising a bond pad;
a package cover over the semiconductor device;
a package lead; and
a bond wire comprising Copper that extends between and is electrically coupled to the bond pad of the semiconductor device and the package lead, the bond wire comprising a first wedge bond at the bond pad and a second wedge bond at the package lead.

13. The semiconductor device package according to claim 12, further comprising:
a second semiconductor device comprising a second bond pad; and
a second bond wire comprising Copper that extends between and is electrically coupled to the bond pad of the semiconductor device and the second bond pad of the second semiconductor device, the second bond wire comprising a first wedge bond at the bond pad and a second wedge bond at the second bond pad.

14. The semiconductor device package according to claim 12, wherein the bond wire comprises a Copper core and a plating layer over the Copper core.

15. The semiconductor device package according to claim 12, further comprising a bond wire pad comprising Gold that extends longitudinally along and on the bond pad of the semiconductor device, wherein the first wedge bond of the bond wire is on the bond wire pad.

16. The semiconductor device package according to claim 12, further comprising:
a first bond wire pad comprising Gold that extends longitudinally along and on the bond pad of the semiconductor device;
a second semiconductor device comprising a second bond pad;
a second bond wire pad comprising Gold that extends longitudinally along and on the second bond pad of the second semiconductor device; and
a second bond wire comprising Copper that extends between and is electrically coupled to the bond pad of the semiconductor device and the second bond pad of the second semiconductor device, the second bond wire comprising a first wedge bond on the first bond wire pad and a second wedge bond on the second bond wire pad.

17. A semiconductor device package, comprising:
a semiconductor device comprising a bond pad;
a package cover over the semiconductor device;
a package lead; and
a bond wire pad comprising Gold that extends longitudinally along and on the bond pad of the semiconductor device.

18. The semiconductor device package according to claim 17, wherein the bond wire pad is wedge bonded to the bond pad of the semiconductor device.

19. The semiconductor device package according to claim 17, further comprising:
a bond wire comprising Copper that extends between and is electrically coupled to the bond pad of the semiconductor device and the package lead, the bond wire comprising a first wedge bond on the bond wire pad and a second wedge bond at the package lead.

20. The semiconductor device package according to claim 19, further comprising:
a second semiconductor device comprising a second bond pad;
a second bond wire pad that extends longitudinally along and on the second bond pad of the second semiconductor device; and
a second bond wire comprising Copper that extends between and is electrically coupled to the bond pad of the semiconductor device and second bond pad of the second semiconductor device, the second bond wire comprising a first wedge bond on the bond wire pad and a second wedge bond on the second bond wire pad.

21-40. (canceled)
